(19) United States
(12) Patent Application Publication
(10) Pub. No.: US 2011/0091694 A1
(43) Pub. Date: Apr. 21, 2011

(54) METHOD FOR FORMING FINE ELECTRODE PATTERNS

(75) Inventors: Isao Hayashi, Tokyo (JP); Mamoru Murakami, Yokohama (JP); Atsuhiko Sato, Utsunomoiya (JP)

(73) Assignee: E. I. DU PONT DE NEMOURS AND COMPANY, Wilmington, DE (US)

(21) Appl. No.: 12/582,227

(22) Filed: Oct. 20, 2009

(51) Int. Cl. B32B 3/10; G03F 7/20

(52) U.S. Cl. 428/195.1; 430/311

(57) ABSTRACT

The present invention is an electrode of an electric device, having a portion at which a pattern is formed using a photosensitive paste, and a portion at which a pattern is formed using a transfer method. Described is a method in which migration at an electrode portion is curtailed by using a photosensitive paste to form a pattern at areas where electrode width is comparatively large, and by forming a pattern using a transfer method at areas where electrode width becomes narrower.

### FIELD OF THE INVENTION

The invention relates to a method of forming an electrically functional pattern on a substrate and an electrode formed by using such method.

### TECHNICAL BACKGROUND OF INVENTION

Photosensitive pastes are one means used in manufacturing fine electrodes in electric devices such as plasma display panels (PDPs) or the like. Photosensitive pastes ordinarily comprise a conductive powder, including materials such as silver, glass frit, an organic binder, monomers, a polymerization initiator, and a solvent. The photosensitive paste is applied on the portion of a substrate where an electrode is to be formed, and then light, corresponding to the polymerization initiator, is irradiated onto desired portions. The monomer component in the irradiated portions undergoes polymerization. These portions are developed thereafter with a developer, as a result of which a desired electrode pattern is formed. The pattern is then fired to yield an electrode in which the conductive component is supported by the glass component.

U.S. Pat. No. 7,052,824 discloses an alternative method for forming a thick film circuit as follows. A photohardenable tacky layer is applied onto a substrate, the photohardenable tacky layer is exposed to a desired pattern and a reverse pattern, and a thick film composition is caused to adhere to non-exposed positions that retain a tacky surface, to form thereby a patterned article in which no thick film composition is adhered at exposed and hardened positions. When this patterned article is heated, the photohardenable tacky layer, including the cured portions, is scattered away, and the thick film becomes directly sintered on the substrate.

As the patterns to be formed become ever finer, they are increasingly susceptible to the problem of metal migration in the conductive pattern. The problem of migration is significant at areas where electrodes become narrower, for instance around tabs. In terms of the conductive component, migration is likelier to occur when silver is used as the conductive component.

Upon comparison of the two pattern formation methods above, it is found that a transfer using a tacky layer is more appropriate for forming fine patterns than a method using a photosensitive paste. However, many existing production lines continue to use photosensitive pastes, and hence a complete switch to a transfer method may require substantial investment in plants and equipment. The present method allows the formation of fine electrode patterns while curtailing migration and keeping capital expenditures to a minimum.

### SUMMARY OF THE INVENTION

The present invention uses a photosensitive paste to form patterns at areas where electrode width is comparatively large, and uses a transfer method to form patterns at areas where electrode width becomes narrower.

An aspect of the present invention is an electrode of an electric device, having a portion at which a pattern is formed using a photosensitive paste and a portion at which a pattern is formed using a transfer method.

Another aspect of the present invention is a process for forming an electrode of an electric device comprising the steps of:
(a) applying a photosensitive paste comprising conductive powder, glass frit, photopolymerizable monomer, organic binder, and solvent onto a substrate;
(b) drying the photosensitive paste;
(c) image-wise exposing the dried photosensitive paste to proceed the polymerization of the photopolymerizable monomer in a prescribed area;
(d) developing the exposed photosensitive paste to form a conductive pattern;
(e) forming a photosensitive layer having a tacky surface on the substrate where the conductive pattern is formed;
(f) image-wise exposing the photosensitive layer to form an imaged layer having tacky and non-tacky areas;
(g) heating the imaged layer;
(h) applying a sheet comprising at least one layer of a thick film composition disposed on a support to the imaged layer wherein the imaged layer is in contact with the thick film composition of the sheet;
(i) removing the support wherein the thick film composition remains on the support in the non-tacky areas of the imaged layer and the thick film composition substantially adheres to the tacky areas of the imaged layer forming a patterned article; and
(j) firing the thick film composition of the patterned article.

### BRIEF DESCRIPTION OF THE DRAWINGS

FIG. 1 is an illustrative diagram depicting an embodiment of the process of the present invention.

FIG. 2 is a schematic figure of an electrode formed by using both photosensitive paste and transfer film.

### DETAILED DESCRIPTION OF THE INVENTION

In the present invention, an electrode pattern of an electric device is formed by combining patterning using a photosensitive paste and patterning using a transfer method. Ordinarily, a finer pattern can be formed by utilizing the transfer method disclosed in U.S. Pat. No. 7,052,824, incorporated herein by reference, in which a pattern is formed using a photosensitive paste at portions where pattern width is comparatively large, while a fine pattern is formed using a transfer method. Migration can be effectively curtailed thereby. Manufacturing processes that employ known photosensitive pastes can be used when only those fine portions where migration is likely to occur are formed by transfer. Existing equipment can be effectively utilized as a result.

The applications of the present invention are not particularly limited. The present invention may be used, for instance, in the manufacture of electrodes for PDPs. Finer display resolutions require finer electrode structures. In particular, multiple electrodes accumulate in a small area around tabs, at the ends of the electrodes. The distance between electrodes becomes as a result extremely narrow in such areas. Migration can be effectively curtailed, with minimum investment in equipment, by using a transfer method to form the periphery of tabs.

Pattern formation methods using photosensitive pastes are widely known and practiced. Patterns may be formed using photosensitive pastes in accordance with known techniques set forth in, for instance, US20070172771, US20060166113 and US20060164011. Improved technologies can also be used. As described above, pattern formation using photosensitive pastes is a well-known feature, and thus a detailed explanation thereof will be omitted.

The transfer method set forth in U.S. Pat. No. 7,052,824, which is incorporated herein by reference, is preferably used herein as the transfer method.

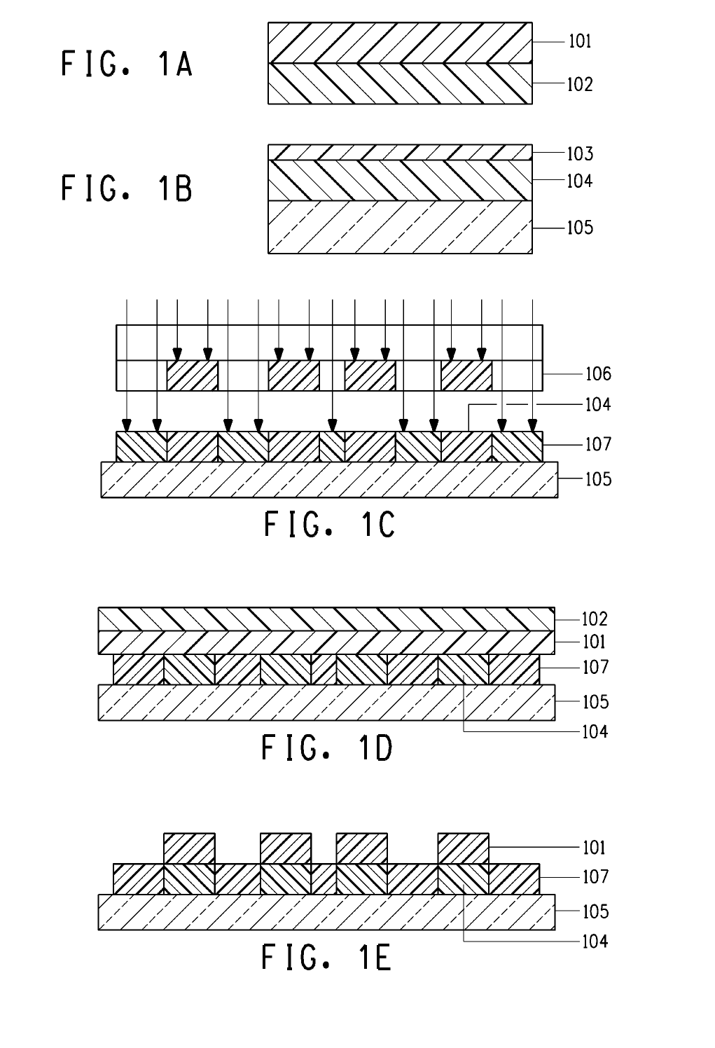

A transfer method is described in FIG. 1. A sheet, referred to as a transfer sheet for illustration purposes, is depicted by FIG. 1(a). It comprises at least one layer of a dried-strippable thick film composition (101), preferably a fineable thick film composition, with powders, inorganic binders and organic mediums as found in the thick film compositions as described hereinabove, deposited on a support (102).

FIG. 1(b) illustrates an assembly wherein a photohardenable layer (104) that has a tacky surface and an optional cover layer (103) such as MYLAR® film are laminated onto a substrate (105). Substrates that may be used in the assembly could be rigid or flexible, and permanent or temporary, and are known by those skilled in the art of circuit assembly. Some examples of substrates include: glass panels (for example, a soda lime glass), glass-ceramic, low-temperature co-fired ceramics, alumina, aluminum oxide, and coated substrates, such as porcelainized steel, glazed ceramic substrates, and insulated metal substrates which are insulated with ceramic, glass or polymer. The substrates could be in their fired or green state. The photohardenable layer is sandwiched between the substrate and the cover layer. The cover layer is transparent for actinic radiation penetration and protects the tacky surface of the photohardenable layer.

As illustrated by FIG. 1(c), image-wise exposing the photohardenable layer with actinic radiation through a patterned photomask (106) causes detackification of the exposed areas of the photohardened layer (107) forming a pattern, for example a circuit pattern which would have electrically functional properties. The circuit pattern is a positive image wherein it would be the same as that found on the photomask.

Preferably, the photohardenable tacky layer (104) is heated after exposure. The heating temperature is preferably not lower than 50° C. A temperature below 50° C. precludes burning off the tacky composition remaining on the surface of the photohardened layer (107) that has not cured owing to the quenching effect. Such being the case, the heating temperature is preferably not lower than 55° C. Preferably, the heating temperature does not exceed 100° C. A heating temperature exceeding 100° C. may cause the photohardenable tacky layer (104), at non-exposed uncured portions, to scatter off excessively, as a result of which the thick film composition fails to adhere, and the thick film pattern cannot be formed. A more preferred heating temperature does not exceed 85° C. The heating time is adjusted in accordance with the heating temperature conditions, but, preferably, does not exceed 40 minutes, more preferably 30 minutes. When the heating time is too short, the curing portions of the photohardenable tacky layer fail to be exposed. Therefore, the heating time is preferably no shorter than 3 minutes, more preferably no shorter than 5 minutes.

As regards the relationship between heating temperature and heating time, the heating temperature ranges preferably from 75° C. to 100° C. when the heating time is less than 15 minutes. When the heating time is 15 minutes to less than 40 minutes, the heating temperature ranges preferably from 45° C. to 75° C.

FIG. 1(d) illustrates a transfer sheet (thick film material side facing the imaged photohardenable layer) laminated onto the photohardenable tacky layer (104) and the photohardened layer (107). The thick film composition (101) will substantially adhere to the unexposed tacky areas of the photohardenable layer.

After peeling the used transfer sheet, which has a reverse circuit pattern formed thereon, off of the photohardenable layer, a thick film circuit pattern is produced forming an article as illustrated in FIG. 1(e). The above process may be repeated, i.e., photohardenable layer, imaging, applying transfer sheet, at least once until desired layer number is reached. The article will then undergo a firing step.

Optionally, depending on the application of the assembly, the assembly may undergo a heat treatment which causes the thick film circuit pattern to diffuse through the tacky non-hardened photohardenable layer onto the substrate surface. This is then followed by a firing step.

The presently available materials that make up the photohardenable layer will be fired or burned-out at about 400° C. Thus, if complete burnout and removal of the photohardenable layer is desired, then the recommended firing temperature should be above 400° C.

The order in which both patterning using a photosensitive paste and pattern formation by transfer succeed each other is not particularly limited, but transfer is preferably carried out after pattern formation using a photosensitive paste. From the viewpoint of simplifying the process, the photosensitive paste and the transfer film are preferably fired simultaneously. Preliminary firing at a lower temperature than the firing temperature may also be carried out after development of the photosensitive paste, to increase the strength of the formed pattern.

When a pattern is formed using a photosensitive paste, without firing, following formation of a pattern by transfer, the transfer pattern tends to peel off during simultaneous firing. Therefore, it is preferable to carry out patterning using a photosensitive paste, followed by pattern formation by transfer after development of the photosensitive paste and, lastly, simultaneous firing of the paste and the transfer film. Specifically, a preferred process includes:
(a) applying a photosensitive paste comprising conductive powder, glass frit, photopolymerizable monomer, organic binder, and solvent onto a substrate;
(b) drying the photosensitive paste;
(c) image-wise exposing the dried photosensitive paste to proceed the polymerization of the photopolymerizable monomer in a prescribed area;
(d) developing the exposed photosensitive paste to form a conductive pattern;
(e) forming a photosensitive layer having a tacky surface on the substrate where the conductive pattern is formed;
(f) image-wise exposing the photosensitive layer to form an imaged layer having tacky and non-tacky areas;
(g) heating the imaged layer;
(h) applying a sheet comprising at least one layer of a thick film composition disposed on a support to the imaged layer wherein the imaged layer is in contact with the thick film composition of the sheet;
(i) removing the support wherein the thick film composition remains on the support in the non-tacky areas of the imaged layer and the thick film composition substantially adheres to the tacky areas of the imaged layer forming a patterned article; and
(j) firing the thick film composition of the patterned article.

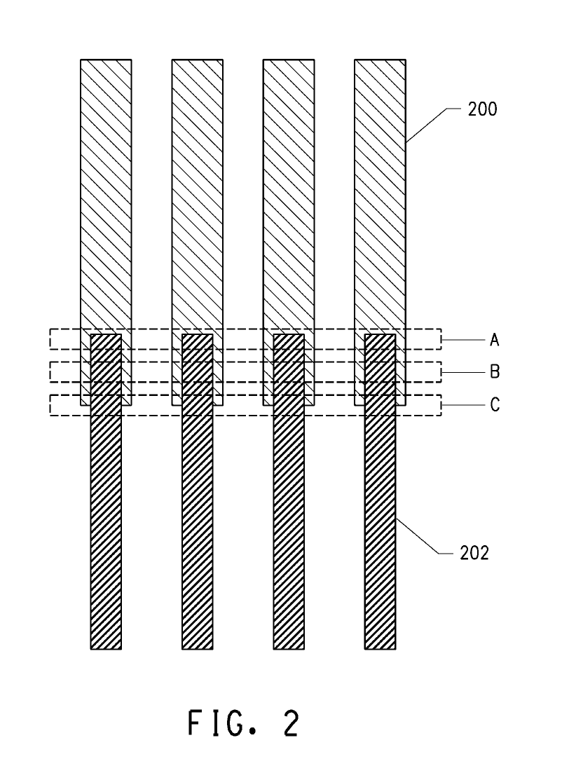

To establish conduction between electrode portions formed by photosensitive paste and electrode portions formed by transfer, the electrodes may be formed in such a manner that the two kinds of electrode portions overlap at connection portions. FIG. 2 is a schematic figure of an electrode formed by using both photosensitive paste 200 and transfer film 202. Causing the photosensitive paste 200 and the transfer film 202 to overlap, as illustrated in FIG. 2, at positions A, B, C, allows keeping to a minimum the rise in resistance that arises from using two kinds of electrode portions, and prevents disconnects, as well.

The surface area over which the electrode portions formed by photosensitive paste and the electrode portions formed by transfer overlap each other is not particularly limited. The surface area of the overlapping portions is preferably large, to afford reliable conduction, but material costs increase as the surface area becomes larger. When introducing a transfer method in the process of forming electrodes using a paste, a smaller transfer surface area requires a lesser supplementary capital expenditure. With the above in mind, the length of overlapping portions in the electrodes, in the current flow direction, ranges preferably from 1 to 100 μm, more preferably from 10 to 30 μm. Transfer films have ordinarily high positional precision, and hence disconnects are unlikely to occur even when the length of the overlapping portions is short.

### EXAMPLES

### Example 1

1. A photosensitive silver paste comprising silver powder, glass frit, an organic binder, monomers, a polymerization initiator and a solvent was printed onto a glass substrate using a screen, and was dried for 5 minutes at 80° C. The paste was exposed to parallel 365 nm UV rays at 400 mJs, using a negative-type photomask for electrodes. The paste was then developed using a 0.4% aqueous solution of Na carbonate, to yield an electrode pattern.

2. After development, the electrode pattern was pre-fired at 450° C. in order to increase the film strength of the electrodes.

3. A transfer film having an adhesive surface was affixed using a hot laminator, at 5 kg/cm and 120° C., onto the substrate having the electrodes formed thereon, in such a manner that the transfer film overlapped with the end portion of the electrode pattern. A cover sheet was disposed on the surface of the transfer film. The transfer film was exposed to parallel 365 nm UV rays at 20 mJs, using a positive-type photomask for electrodes, and then the cover film was stripped off. The exposed sites were non-adhesive. A toner tape having a thick-film silver paste coated thereon was disposed on the transfer film on which adhesive portions and non-adhesive portions had been formed. The whole was then run, at normal temperature, through a high-pressure laminator at 30 kg/cm. The thick-film silver paste was transferred onto the adhesive portions, to form an electrode pattern.

4. The substrate having the electrode pattern formed thereon was fired according to a peak firing profile having a peak temperature at 580° C., to yield the electrodes. The pattern shape of the electrodes was examined in detail, and the resistance value of the electrodes was measured.

### Example 2

Electrodes were formed in the same way as in Example 1, but omitting herein the preliminary firing (process 2).

### Comparative Example 1

Electrodes were formed in accordance with the process (1) of Example 1, but using herein only the photosensitive silver paste employed in Example 1. The electrodes were obtained thereafter by firing according to process (3) and (4).

### Comparative Example 2

Electrodes were formed according to process (2) of Example 1, using herein only the thin film employed in Example 1. The electrodes were obtained thereafter by firing according to process (3) and (4).

### Evaluation

As Table 1 shows, electrodes having a low resistance value were manufactured by using concomitantly a photosensitive paste and a transfer film. Although pattern strength could be increased by preliminary firing (process 2), it was also possible to form electrodes free of defects even when no preliminary firing was performed.

Migration can be curtailed with little capital expenditure by using a photosensitive paste and transfer films in combination and by effectively utilizing existing equipment. For instance, wide patterns are formed in the electrodes using a photosensitive paste, while narrow patterns in the vicinity of terminals or the like are formed using a transfer method. Migration is effectively curtailed thereby at portions where fine patterns come close to each other.

TABLE 1

| | | | Comparative | Comparative |
|---|---|---|---|---|
| | Example 1 | Example 2 | Example 1 | Example 2 |
| Type | photosensitive paste/ | photosensitive paste/ | photosensitive paste | transferred film |
| | transferred film | transferred film | | |
| Thickness of Electrode | 2.4/1.8 | 2.2/1.8 | 2.2 | 1.6 |
| (micrometer) | | | | |
| Resistance (ohm) | 5.0 | 4.5 | 3.9 | 5.7 |

We claim:

1. An electrode of an electric device, having a portion at which a pattern is formed using a photosensitive paste, and a portion at which a pattern is formed using a transfer method.

2. The electrode of an electric device according to claim 1, wherein the portion at which a pattern is formed using a transfer method overlaps the top of the portion at which a pattern is formed using a photosensitive paste, at a conduction portion between the portion at which a pattern is formed using a photosensitive paste and the portion at which a pattern is formed using a transfer method.

3. The electrode of an electric device according to claim 2 wherein the overlap distance between the pattern formed using a transfer method and the pattern formed using a photosensitive paste is 1 to 100 μm.

4. The electrode of an electric device according to claim 2 wherein the overlap distance between the pattern formed using a transfer method and the pattern formed using a photosensitive paste is from 10 to 30 μm.

5. A process for forming an electrode of electric device comprising the steps of:
(a) applying a photosensitive paste comprising conductive powder, glass frit, photopolymerizable monomer, organic binder, and solvent onto a substrate;
(b) drying the photosensitive paste;
(c) image-wise exposing the dried photosensitive paste to proceed the polymerization of the photopolymerizable monomer in a prescribed area;
(d) developing the exposed photosensitive paste to form a conductive pattern;
(e) forming a photosensitive layer having a tacky surface on the substrate where the conductive pattern is formed;
(f) image-wise exposing the photosensitive layer to form an imaged layer having tacky and non-tacky areas;
(g) heating the imaged layer;
(h) applying a sheet comprising at least one layer of a thick film composition disposed on a support to the imaged layer wherein the imaged layer is in contact with the thick film composition of the sheet;
(i) removing the support wherein the thick film composition remains on the support in the non-tacky areas of the imaged layer and the thick film composition substantially adheres to the tacky areas of the imaged layer forming a patterned article; and
(j) firing the thick film composition of the patterned article.
